(19) United States
(12) Patent Application Publication
(10) Pub. No.: US 2025/0079319 A1
(43) Pub. Date: Mar. 6, 2025

(54) SEMICONDUCTOR PACKAGE AND METHOD OF FABRICATING THE SAME

(71) Applicant: Samsung Electronics Co., Ltd., Suwon-si (KR)

(72) Inventors: Jeongseok KIM, Suwon-si (KR); Jaeseong KIM, Suwon-si (KR); Tae Wook KIM, Suwon-si (KR); Yejin LEE, Suwon-si (KR); Jooyoung CHOI, Suwon-si (KR); Sangseok HONG, Suwon-si (KR)

(73) Assignee: Samsung Electronics Co., Ltd., Suwon-si (KR)

(21) Appl. No.: 18/737,402

(22) Filed: Jun. 7, 2024

(30) Foreign Application Priority Data
Aug. 31, 2023 (KR) 10-2023-0115252

(51) Int. Cl. H01L 23/538; H01L 23/00; H01L 23/31; H01L 23/36; H01L 23/49; H01L 23/498; H01L 25/16; H01Q 1/22

(52) U.S. Cl. CPC H01L 23/5383; H01L 23/3107; H01L 23/36; H01L 23/49; H01L 25/16; H01Q 1/2283; H01L 23/49816; H01L 24/16; H01L 24/32; H01L 24/73; H01L 2224/16227; H01L 2224/32225; H01L 2224/73204; H01L 2924/1421; H01L 2924/15174

(57) ABSTRACT

A semiconductor package may include a first redistribution substrate, a first semiconductor chip disposed on the first redistribution substrate, a second semiconductor chip horizontally spaced apart from the first semiconductor chip, a mold layer provided on the first redistribution substrate to enclose the first and second semiconductor chips, a second redistribution substrate disposed on the mold layer, a connection member, which is provided at a side of the first and second semiconductor chips to connect the first redistribution substrate to the second redistribution substrate, and an antenna substrate attached to the second redistribution substrate using an adhesive layer. The antenna substrate may include a core portion, an antenna pattern provided on a top surface of the core portion, and a wiring pattern provided on a bottom surface of the core portion.

### CROSS-REFERENCE TO RELATED APPLICATIONS

This U.S. non-provisional patent application claims priority under 35 U.S.C. § 119 to Korean Patent Application No. 10-2023-0115252, filed on Aug. 31, 2023, in the Korean Intellectual Property Office, the entire contents of which are hereby incorporated by reference. pattern.

### BACKGROUND

Some example embodiments of inventive concepts relate to a semiconductor package including an antenna pattern, and to a method for fabricating the same.

With recent advancements in the electronics industry, the demand for high-performance, high-speed, and compact electronic components has been steadily increasing. As a result, packaging technologies have been developed to enable the mounting of multiple semiconductor chips within a single package.

A semiconductor package may be configured to facilitate the use of an integrated circuit chip as a component in an electronic product. In general, a semiconductor package may include a printed circuit board (PCB) and a semiconductor chip mounted on the PCB and electrically connected to the PCB by bonding wires or bumps. With the recent developments in the electronics industry, semiconductor package technologies are developing in various ways with the goal of miniaturization, weight reduction, and manufacturing cost reduction. Furthermore, as the utilization of this technology expands to various fields, including mass storage devices, several types of semiconductor packages are emerging.

In a semiconductor package, components used to realize a circuit with a specific function may be integrated in a single chip, and such a chip may be mounted on a package substrate. The components may include, e.g., semiconductor devices, resistors, capacitors, and interconnection wires connecting them. If the chip has intended functions of transmitting or receiving wireless signals, it is useful to develop a semiconductor package in which an antenna and other electronic components (e.g., RFIC, PMIC, passive parts, etc.) are integrated, and which is configured to reduce or minimize loss of high frequency signals.

For a semiconductor package with a wireless communication function, it is useful to prevent or suppress the signal loss issue from occurring when the signals are exchanged between a radio frequency integrated circuit (RFIC) and the antenna. Furthermore, there is a need to develop design technology that can stably integrate the RFIC and the antenna in a package, with reduced design error and an increased degree of freedom or flexibility in the design process.

### SUMMARY

Some example embodiments of inventive concepts describe a small-sized semiconductor package with an antenna.

Some example embodiments of inventive concepts describe a semiconductor package with improved electrical characteristics.

According to some example embodiments of inventive concepts, a semiconductor package may include a first redistribution substrate, a first semiconductor chip on the first redistribution substrate, a second semiconductor chip horizontally apart from the first semiconductor chip, a mold layer on the first redistribution substrate and enclosing the first and second semiconductor chips, a second redistribution substrate on the mold layer, a connection member horizontally apart from the first and second semiconductor chips and connecting the first redistribution substrate to the second redistribution substrate, and an antenna substrate attached to the second redistribution substrate by an adhesive layer. The antenna substrate may include a core portion, an antenna pattern on a top surface of the core portion, and a wiring pattern on a bottom surface of the core portion.

According to some example embodiments of inventive concepts, a semiconductor package may include a first redistribution substrate, a first semiconductor chip on a top surface of the first redistribution substrate, a second redistribution substrate on the first semiconductor chip, a connection member at a side of the first semiconductor chip and connecting the first redistribution substrate to the second redistribution substrate, an antenna substrate on the second redistribution substrate, a heat-dissipation pad on a bottom surface of the first redistribution substrate, and a heat-dissipation via pattern vertically penetrating the first redistribution substrate and connecting the heat-dissipation pad to the first semiconductor chip.

According to some example embodiments of inventive concepts, a semiconductor package may include a first redistribution substrate, a first semiconductor chip on a top surface of the first redistribution substrate, a second semiconductor chip on the first redistribution substrate and horizontally apart from the first semiconductor chip, a mold layer on the top surface of the first redistribution substrate and enclosing the first and second semiconductor chips, a second redistribution substrate provided on the mold layer, an antenna substrate disposed on the second redistribution substrate, a connector provided on the second redistribution substrate and horizontally spaced apart from the antenna substrate, and a vertical connection conductor vertically penetrating the mold layer and connecting the first redistribution substrate to the second redistribution substrate. The vertical connection conductor may be shaped like a partition wall enclosing the first and second semiconductor chips.

### BRIEF DESCRIPTION OF THE DRAWINGS

FIG. 1 is a sectional view illustrating a semiconductor package according to some example embodiments of inventive concepts.

FIGS. 2 and 3 are plan views, each of which illustrates a semiconductor package according to some example embodiments of inventive concepts.

FIGS. 4 to 7 are sectional views, each of which illustrates a semiconductor package according to some example embodiments of inventive concepts.

FIGS. 8 to 12 are sectional views illustrating a method of fabricating a semiconductor package, according to some example embodiments of inventive concepts.

### DETAILED DESCRIPTION

Example embodiments of some inventive concepts will now be described more fully with reference to the accompanying drawings.

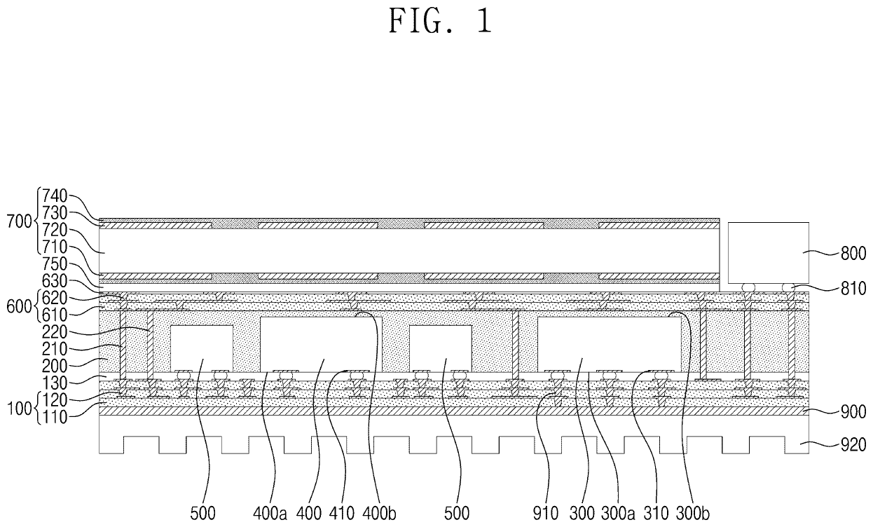

FIG. 1 is a sectional view illustrating a semiconductor package according to some example embodiments of inventive concepts.

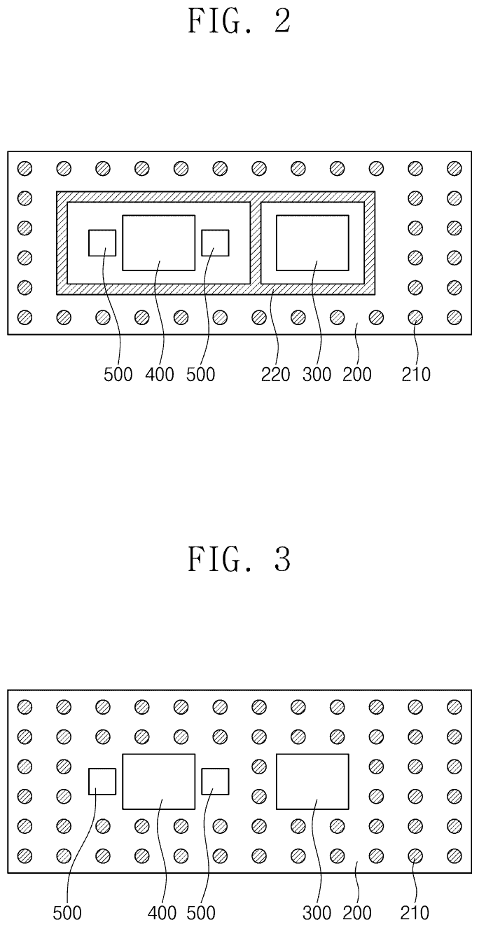

FIGS. 2 and 3 are plan views, each of which illustrates a semiconductor package according to some example embodiments of inventive concepts.

Referring to FIG. 1, a first redistribution substrate 100 may be provided. The first redistribution substrate 100 may include one substrate wiring layer or two or more substrate wiring layers, which are stacked on each other. According to some example embodiments of inventive concepts, the substrate wiring layer may mean a wiring layer that includes a patterned structure of a single insulating layer and a patterned structure of a single conductive layer. For example, conductive patterns in each substrate wiring layer may be horizontally extending wiring patterns that do not vertically overlap with each other. Each of the substrate wiring layers may include at least one of first insulating pattern 110 and a first conductive pattern 120 in the first insulating pattern 110. The first conductive pattern 120 in one of the substrate wiring layers may be electrically connected to a first conductive pattern 120 in a neighboring one of the substrate wiring layers. Hereinafter, the first insulating pattern 110 and the first conductive pattern 120 will be described based on one of the substrate wiring layers, but example embodiments are not limited thereto

The first insulating pattern 110 may be formed of or include at least one of inorganic insulating materials (e.g., silicon oxide (SiOx) or silicon nitride (SiNx)). Alternatively, the first insulating pattern 110 may be formed of or include at least one polymer material. The first insulating pattern 110 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers, but example embodiments are not limited thereto.

At least a portion of first conductive pattern 120 may be provided on a top surface of the first insulating pattern 110. The first conductive pattern 120 may include a protruding pattern that extends to a region on the top surface of the first insulating pattern 110. The first conductive pattern 120 may horizontally extend on the top surface of the first insulating pattern 110. The first conductive pattern 120 on a top surface of a first insulating pattern 110 may be covered with another first insulating pattern 110 thereon. The first conductive pattern 120 may comprise a pad or wiring portion of the substrate wiring layer. For example, the first conductive pattern 120 may be an element used for a horizontal redistribution in the first redistribution substrate 100. The first conductive pattern 120 may include a conductive material. For example, the first conductive pattern 120 may be formed of or include copper (Cu), but example embodiments are not limited thereto.

The first conductive pattern 120 may have a damascene structure, e.g., a structure formed by a dual-damascene process. For example, the first conductive pattern 120 may have a via portion that is formed near a bottom surface thereof and has a protruding shape. The via portion may be an element that connects vertically adjacent ones of the first conductive patterns 120 to each other. For example, the via portion may extend from the bottom surface of the first conductive pattern 120 to penetrate the first insulating pattern 110 and may be coupled to a top surface of the first conductive pattern 120 in another substrate wiring layer thereunder. For example, an upper portion of a first conductive pattern 120 that is placed at a level higher than the first insulating pattern 110, may be a head portion, which may comprise horizontal wire or pad, and the via portion of the first conductive pattern 120 may be a tail portion. The first conductive pattern 120 may have a shape the same as, substantially the same as, or similar to the letter “T”, but example embodiments are not limited thereto.

FIG. 1 illustrates an example embodiment, in which the via portion of the first conductive pattern 120 is connected to the bottom surface of the first conductive pattern 120, but inventive concepts are not limited thereto. The tail portion of the first conductive pattern 120 may be placed at a level higher than the head portion and may have a protruding shape, and, the first conductive pattern 120 may have a shape the same as, substantially the same as, or similar to an inverted letter “T”. For example, the first conductive pattern 120 may have a via portion that is formed near a top surface thereof and has a protruding shape. The via portion may be an element that is used to vertically connect adjacent ones of the first conductive patterns 120 to each other. For example, the via portion may extend from the top surface of the first conductive pattern 120 to penetrate the first insulating pattern 110 and may be coupled to a bottom surface of another first conductive pattern 120 thereon. For example, a lower portion of the first conductive pattern 120, which is placed at a level lower than a bottom surface of the first insulating pattern 110, may be a head portion, which may be used as a horizontal wire or a pad, and the via portion of the first conductive pattern 120 may be a tail portion. Hereinafter, inventive concepts and example embodiments thereof will be further described with reference to the example embodiment of FIG. 1.

The head portions of the first conductive patterns 120 in the uppermost one of the substrate wiring layers may serve as first, second, and third substrate pads that are respectively used to mount a first semiconductor chip 300, a second semiconductor chip 400, and a passive device 500, which will be described below, on the first redistribution substrate 100.

A first semiconductor chip 300 may be disposed on the first redistribution substrate 100. The first semiconductor chip 300 may be provided in a face-down manner. The first semiconductor chip 300 may have a bottom surface 300a facing the first redistribution substrate 100 and a top surface 300b opposite to the bottom surface 300a. The bottom surface 300a may be, e.g., an active surface of the first semiconductor chip 300. The top surface 300b may be, e.g., an inactive surface of the first semiconductor chip 300. The first semiconductor chip 300 may be formed of or include a semiconductor material (e.g., silicon (Si)). The first semiconductor chip 300 may be a communication semiconductor chip which may be electrically connected to an antenna substrate 700, which will be described below, or may be configured to transmit or receive signals to or from the antenna substrate 700. The first semiconductor chip 300 may include a signal processing circuit or the like, which may be used to process wireless signals that are transmitted or received through the antenna substrate 700. For example, the first semiconductor chip 300 may include a radio-frequency integrated circuit (RFIC), but example embodiments are not limited thereto.

The first semiconductor chip 300 may include, e.g., first chip pads 310 that are provided on the bottom surface 300a. The first chip pads 310 may be electrically connected to the first semiconductor chip 300, for example to an integrated circuit in the first semiconductor chip 300.

Connection terminals including, e.g., solder balls or solder bumps, may be provided on the first chip pads 310 of the first semiconductor chip 300. The first semiconductor chip 300 may be mounted on the first substrate pads of the first redistribution substrate 100 using the connection terminals. For example, the first semiconductor chip 300 may be mounted on the first redistribution substrate 100 in a flip-chip bonding manner, but example embodiments are not limited thereto

While FIG. 1 illustrates example embodiments in which the first semiconductor chip 300 is mounted on the first redistribution substrate 100 in a flip-chip bonding manner, example embodiments are not limited thereto. For example, the bottom surface 300a of the first semiconductor chip 300 may be in contact with a top surface of the first redistribution substrate 100. The first chip pads 310 may be electrically connected to the first conductive patterns 120 of the first redistribution substrate 100. For example, on a contact surface between the first semiconductor chip 300 and the first redistribution substrate 100, at least one of the first chip pads 310 may be in direct contact with at least one of the first substrate pads of the first redistribution substrate 100. Hereinafter, some inventive concepts will be further described with reference to the example embodiments of FIG. 1.

A second semiconductor chip 400 may be disposed on the first redistribution substrate 100. The second semiconductor chip 400 may be horizontally spaced apart from the first semiconductor chip 300. The second semiconductor chip 400 may be provided in a face-down manner. The second semiconductor chip 400 may have a bottom surface 400a facing the first redistribution substrate 100 and a top surface 400b opposite to the bottom surface 400a. The bottom surface 400a may be an active surface of the second semiconductor chip 400. The top surface 400b may be an inactive surface of the second semiconductor chip 400. The second semiconductor chip 400 may include, for example, a semiconductor material (e.g., silicon (Si)). The second semiconductor chip 400 may include one or more of various electronic devices (e.g., a power management integrated circuit (PMIC), a modem, a transceiver, a power amplifier module (PAM), a frequency filter, or a low noise amplifier (LNA)), which may be used to drive the first semiconductor chip 300. The second semiconductor chip 400 may include second chip pads 410 that are provided on the bottom surface 400a. The second chip pads 410 may be, for example, electrically connected to an integrated circuit in the second semiconductor chip 400, but example embodiments are not limited thereto.

Connection terminals including e.g., solder balls or solder bumps, may be provided on the second chip pads 410 of the second semiconductor chip 400. The second semiconductor chip 400 may be mounted on the second substrate pads of the first redistribution substrate 100 using the connection terminals. For example, the second semiconductor chip 400 may be mounted on the first redistribution substrate 100 in a flip-chip bonding manner.

The method of mounting the second semiconductor chip 400 is not limited to the flip-chip bonding method, as in the case with the method of mounting the first semiconductor chip 300. In an embodiment, the bottom surface 400a of the second semiconductor chip 400 may be in contact with the top surface of the first redistribution substrate 100, and on a contact surface between the second semiconductor chip 400 and the first redistribution substrate 100, the second chip pads 410 may be in direct contact with the second substrate pads of the first redistribution substrate 100. Hereinafter, some inventive concepts will be further described with reference to the example embodiments of FIG. 1.

At least one passive device 500 may be disposed on the first redistribution substrate 100. The passive device 500 may include pads that are provided on a bottom surface thereof. Connection terminals including, e.g., solder balls or solder bumps, may be provided on the pads of the passive device 500. The passive device 500 may be mounted on the first redistribution substrate 100. For example, the passive device 500 may be mounted on the third substrate pads of the first redistribution substrate 100 using the connection terminals. In the case where a plurality of passive devices 500 are provided, the passive devices 500 may be horizontally spaced apart from the second semiconductor chip 400 on the top surface of the first redistribution substrate 100. The passive device 500 may include, for example, at least one of a capacitor, an inductor, a resistor, a memristor, or an integrated passive device (IPD), but example embodiments are not limited thereto.

An under-fill layer 130 may be provided between the top surface of the first redistribution substrate 100 and bottom surfaces of the first semiconductor chip 300, the second semiconductor chip 400, and the passive device 500. The under-fill layer 130 may fill spaces between the first redistribution substrate 100 and the first semiconductor chip 300, the second semiconductor chip 400, and the passive device 500 and may at least partially enclose the connection terminals. FIG. 1 illustrates some example embodiments in which the under-fill layer 130 is provided to cover the entire top surface of the first redistribution substrate 100, but the example embodiments are not limited thereto. In an example embodiment, a plurality of under-fill layers 130 may be locally provided in regions between the first redistribution substrate 100 and the first semiconductor chip 300, between the first redistribution substrate 100 and the second semiconductor chip 400, and between the first redistribution substrate 100 and the passive device 500. The under-fill layers 130 may not, for example, be provided on regions of the first redistribution substrate 100 where the first semiconductor chip 300, the second semiconductor chip 400, and the passive device 500 are absent, and in such regions, the top surface of the first redistribution substrate 100 may be exposed to the under-fill layers 130.

In an example embodiment according to FIG. 1, a mold layer 200 may be provided on the first redistribution substrate 100. The mold layer 200 may cover a top surface of the under-fill layer 130. The mold layer 200 may at least partially enclose the first semiconductor chip 300, the second semiconductor chip 400, and the passive device 500. The mold layer 200 may at least partially cover the first semiconductor chip 300, the second semiconductor chip 400, and the passive device 500. Alternatively, the top surface 300b of the first semiconductor chip 300, the top surface 400b of the second semiconductor chip 400, and the top surface of the passive device 500 may be exposed to a region on a top surface of the mold layer 200. The mold layer 200 may include, for example, one or more insulating materials. For example, the mold layer 200 may be formed of or include an epoxy molding compound (EMC), but example embodiments are not limited thereto.

A heat-dissipation pad 900 may be provided on the bottom surface of the first redistribution substrate 100 and cover at least a portion of the bottom surface of the first redistribution substrate 100. For example, the heat-dissipation pad 900 may be disposed to be in contact with the bottom surface of the first redistribution substrate 100. The heat-dissipation pad 900 may transfer heat, which may be generated from the first semiconductor chip 300 or the second semiconductor chip 400, to the outside.

A plurality of heat-dissipation conductive patterns 910 may be disposed in the first redistribution substrate 100 to vertically penetrate the first redistribution substrate 100. The heat-dissipation conductive patterns 910 may be some of the first conductive patterns 120 of the first redistribution substrate 100. For example, each of the heat-dissipation conductive patterns 910 may include a head portion and a tail portion, which are connected to each other as to form a single object. The head portion may be disposed on the top surface of the first insulating pattern 110, and the tail portion may be extended in a vertical direction to penetrate at least one of the first insulating patterns 110. Each of the heat-dissipation conductive patterns 910 may be formed of or include the same, substantially the same, or similar material as the first conductive patterns 120.

Uppermost ones of the heat-dissipation conductive patterns 910 may be connected to the first and second substrate pads of the first redistribution substrate 100, and lowermost ones of the heat-dissipation conductive patterns 910 may be connected to the heat-dissipation pad 900. The heat-dissipation pad 900 may be used to transfer heat, for example heat generated from the first and second semiconductor chips 300 and 400, to the outside. For example, heat, which may be generated from the first and second semiconductor chips 300 and 400, may be transferred to the heat-dissipation pad 900 through the connection terminals, which connect the first and second semiconductor chips 300 and 400 to the first redistribution substrate 100, and the heat-dissipation conductive patterns 910. The heat may be transferred to the outside through the heat-dissipation pad 900. For example, it may be possible to quickly transfer heat, which may be generated from the first and second semiconductor chips 300 and 400, to a region below the first redistribution substrate 100, and thereby realize a semiconductor package with improved heat-dissipation characteristics.

Some of the heat-dissipation conductive patterns 910 may be electrically disconnected from the first semiconductor chip 300, the second semiconductor chip 400, and the passive devices 500. In addition, at least one of the heat-dissipation conductive patterns 910 may not be directly connected to the heat-dissipation pad 900. For example, at least one of the heat-dissipation conductive patterns 910 may be in an electrically-floated state in the first redistribution substrate 100, but example embodiments are not limited thereto

According to Some example embodiments of inventive concepts, a heat sink 920 may be provided on the bottom surface of the first redistribution substrate 100. The heat sink 920 may be provided to cover a bottom surface of the heat-dissipation pad 900 at least partially. For example, the heat sink 920 may be disposed to be in contact with the bottom surface of the heat-dissipation pad 900. Although not shown, example embodiments may include a bonding element provided to bond the heat sink 920 to the heat-dissipation pad 900. In an example embodiment, the bonding element may not be provided.

The heat sink 920 may be configured to transfer heat, which may be generated by the first and second semiconductor chips 300 and 400, to the outside. For example, heat generated from the first and second semiconductor chips 300 and 400 may be transferred to the heat sink 920 through the heat-dissipation pad 900. The heat may be transferred to the outside through the heat sink 920.

The heat sink 920 may include, for example, at least one or more materials having high thermal conductivity (e.g., metallic materials, ceramic materials, carbon materials, or polymer materials). The heat sink 920 may, for example, have an uneven structure (e.g., a rectilinear serrated pattern or finned heat sink profile), as shown in FIG. 1, but example embodiments are not limited thereto. The uneven structure may allow for an increase in the surface area of the heat sink 920 that may be in contact with the air layer in the outside region. Due to the increased surface area of the heat sink 920, heat generated by the first and second semiconductor chips 300 and 400, may be more effectively transferred to a region below the first redistribution substrate 100. In some example embodiments, the heat sink 920 may not be provided.

The semiconductor package may include a metal post 210. The metal post 210 may be horizontally spaced apart from the first and second semiconductor chips 300 and 400. The metal post 210 may be a connection member placed in proximity to the first and second semiconductor chips 300 and 400 to connect the first redistribution substrate 100 to a second redistribution substrate 600 to be described below. The metal post 210 may be provided to vertically penetrate the mold layer 200. An end of the metal post 210 may be connected to at least one of the first conductive patterns 120 of the first redistribution substrate 100, and an opposite end of the metal post 210 may be connected to at least one of second conductive patterns 620 of the second redistribution substrate 600, which will be described below. Although not shown, a width of the metal post 210 may, for example, increase as a distance from the first redistribution substrate 100 increases. For example, the metal post 210 may be provided to have a tapered section. Alternatively, the metal post 210 may be provided to have a linear section or to have a constant width regardless of a vertical position. Although not shown, a seed layer and/or a barrier layer may be provided between the metal post 210 and the mold layer 200. For example, the seed or barrier layer may be provided to cover bottom and side surfaces of the metal post 210 at least partially. In some example embodiments, a plurality of metal posts 210 may be provided. The metal post 210 may be formed of or include at least one or more metallic materials. The metallic material may include, for example, at least one of copper (Cu), aluminum (Al), silver (Ag), tin (Sn), gold (Au), nickel (Ni), lead (Pb), titanium (Ti), or alloys thereof, but example embodiments are not limited thereto.

Referring to FIGS. 1 and 2, a vertical connection conductor 220 may be provided. The vertical connection conductor 220 may be provided to vertically penetrate the mold layer 200. The vertical connection conductor 220 may connect the first redistribution substrate 100 to the second redistribution substrate 600. The vertical connection conductor 220 may be horizontally spaced apart from the first and second semiconductor chips 300 and 400. The vertical connection conductor 220 may shield an electromagnetic wave, which may be generated by the first or second semiconductor chip 300 or 400, or may prevent or reduce the chance of an electromagnetic wave, which may be incident from an external component, from entering or contacting the first or second semiconductor chip 300 or 400.

An end of the vertical connection conductor 220 may be connected to at least one of the first conductive patterns 120 of the first redistribution substrate 100. An opposite end of the vertical connection conductor 220 may be connected to at least one of the second conductive patterns 620 of the second redistribution substrate 600, which will be described below. The vertical connection conductor 220 may have a shape the same as, substantially the same as, or similar to a partition wall crossing a region between the first and second semiconductor chips 300 and 400, individually enclosing each of the first and second semiconductor chips 300 and 400, and/or enclosing all of the first and second semiconductor chips 300 and 400.

In an embodiment, the vertical connection conductor 220 may be formed through a process the same as, substantially the same as, or similar to the process of forming the metal post 210. The vertical connection conductor 220 may be formed of or include the same, substantially the same, or similar to metallic material or materials as in the metal post 210. The metallic material may include, for example, one or more of copper (Cu), aluminum (Al), silver (Ag), tin (Sn), gold (Au), nickel (Ni), lead (Pb), titanium (Ti), or alloys thereof, but example embodiments are not limited thereto.

FIG. 2 illustrates example embodiments in which the vertical connection conductor 220 is provided to have a shape of the same as, substantially the same as, or similar to a partition wall, but example embodiments are not limited thereto. As shown in FIG. 3, the semiconductor package may not include the vertical connection conductor 220. In the case where the vertical connection conductor 220 is absent, a plurality of metal posts 210 may be provided in a region where the vertical connection conductor 220 is not provided, but example embodiments are not limited thereto.

The second redistribution substrate 600 may be provided on the top surface of the mold layer 200. The second redistribution substrate 600 may at least partially cover the top surface of the mold layer 200. The second redistribution substrate 600 may include one or more substrate wiring layers, which are sequentially stacked on the top surface of the mold layer 200. Each of the substrate wiring layers may include, for example, a second insulating pattern 610 and a second conductive pattern 620. The second conductive pattern 620 in any one of the substrate wiring layers may be electrically connected to the second conductive patterns 620 in a neighboring of the substrate wiring layers. Hereinafter, the second insulating pattern 610 and the second conductive pattern 620 will be described based on one of the substrate wiring layers.

The second insulating pattern 610 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers, but example embodiments are not limited thereto.

The second conductive pattern 620 may be provided on a top surface of the second insulating pattern 610. The second conductive pattern 620 may include, for example, a protruding pattern that extends to a region on the top surface of the second insulating pattern 610. The second conductive pattern 620 may horizontally extend on the top surface of the second insulating pattern 610. The second conductive pattern 620 on the top surface of the second insulating pattern 610 may be at least partially covered with another second insulating pattern 610 thereon. In an example embodiment, the second conductive pattern 620 may comprise a pad or wiring portion of the substrate wiring layer. For example, the second conductive pattern 620 may be an element used for horizontal redistribution in the second redistribution substrate 600. The second conductive pattern 620 may include, for example, at least a conductive material. For example, the second conductive pattern 620 may be formed of or include at least copper (Cu), but example embodiments are not limited thereto.

The second conductive pattern 620 may have a damascene structure, for example a structure formed by a dual-damascene process. For example, the second conductive pattern 620 may have a via portion that is formed near a bottom surface thereof and has a protruding shape. The via portion may be an element that is used to connect the second conductive patterns 620 in vertically adjacent ones of the second wiring layers to each other. For example, the via portion may be extended from the bottom surface of the second conductive pattern 620 to penetrate the second insulating pattern 610 and may be coupled to a top surface of the second conductive pattern 620 in another substrate wiring layer thereunder. For example, an upper portion of the second conductive pattern 620 which is placed at a level higher than the second insulating pattern 610 may be a head portion, which may be used as a horizontal wire or a pad, and the via portion of the second conductive pattern 620 may be a tail portion. The second conductive pattern 620 may have a shape the same as, substantially the same as, or similar to the letter “T,” but example embodiments are not limited thereto.

The second conductive pattern 620 in the lowermost one of the substrate wiring layers may be provided to penetrate the second insulating pattern 610 and may be coupled to the metal post 210. For example, the first redistribution substrate 100 and the second redistribution substrate 600 may be electrically connected to each other through the metal post 210.

The head portion of the second conductive pattern 620 in the uppermost one of the substrate wiring layers may serve as first upper pads for mounting the antenna substrate 700 and second upper pads for mounting a connector 800, to be described below. The first and second upper pads may be provided on a top surface of the second redistribution substrate 600. The first and second upper pads may be some of the second conductive patterns 620, which are exposed to the second insulating patterns 610 of the second redistribution substrate 600, or may be additional pads, which are placed on the second insulating patterns 610 of the second redistribution substrate 600 and are connected to the second conductive patterns 620. The first and second upper pads may be formed of or include at least one of conductive materials. For example, the first and second upper pads may be formed of or include at least copper (Cu), but example embodiments are not limited thereto.

A substrate protection layer 630 may be provided on the top surface of the second redistribution substrate 600. The substrate protection layer 630 may cover the uppermost one of the substrate wiring layers. The substrate protection layer 630 may be provided to cover the uppermost one of the second insulating patterns 610 and to enclose the first and second upper pads. The first and second upper pads may be exposed to a region on a top surface of the substrate protection layer 630. The substrate protection layer 630 may be formed of or include, for example, at least one of an insulating polymer or a photoimageable polymer, but example embodiments are not limited thereto In some example embodiments, the substrate protection layer 630 may not be provided.

The antenna substrate 700 may be disposed on the top surface of the second redistribution substrate 600. The antenna substrate 700 may be, for example, attached to the second redistribution substrate 600 using an adhesive layer 750. The top surface of the second redistribution substrate 600 and a bottom surface of the antenna substrate 700 may face each other. The adhesive layer 750 may be provided on at least one of the top surface of the second redistribution substrate 600 and the bottom surface of the antenna substrate 700. The adhesive layer 750 may, for example, be used to attach the top surface of the second redistribution substrate 600 to the bottom surface of the antenna substrate 700. The adhesive layer 750 may include, for example, a die attach film (DAF). The antenna substrate 700 may comprise a multi-layered printed circuit board including a core portion 720, an antenna pattern 730 on a top surface of the core portion 720, and/or a conductive pattern 710 on a bottom surface of the core portion 720, but example embodiments are not limited thereto.

The antenna pattern 730 may comprise a patch antenna that is composed of a plurality of patch patterns. The antenna pattern 730 may have a structure and/or shape that is suitable for communication within a predetermined wavelength range, and it may be configured to transmit or receive wireless signals in a millimeter wavelength range. The antenna pattern 730 may serve as a radiator and/or a director of the antenna. However, inventive concepts are not limited to this example embodiment, and the antenna pattern 730 may have various structures capable of transmitting and receiving wireless signals. The antenna pattern 730 may be formed of or include, for example, at least one of conductive materials (e.g., copper (Cu), aluminum (Al), silver (Ag), tin (Sn), gold (Au), nickel (Ni), lead (Pb), titanium (Ti), or alloys thereof), but example embodiments are not limited thereto. The antenna pattern 730 may be formed by, for example, an AP, SAP, MSAP, or TT process, and the number of layers constituting the antenna pattern 730 may be greater or smaller than that shown in FIG. 1, but example embodiments are not limited thereto.

The conductive pattern 710 may be used, for example, to increase the bandwidth in wireless communication using the antenna pattern 730. The conductive pattern 710 may be spaced apart from the antenna pattern 730 in a vertical direction with the core portion 720 interposed therebetween. When viewed in a plan view, the conductive pattern 710 may be, for example, a polygonal (e.g., circular or rectangular) patch antenna or may be a line-shaped pattern that is formed on the bottom surface of the core portion 720. When viewed in a plan view, the conductive pattern 710 may have the same shape as the antenna pattern 730 and may at least partially overlap with the antenna pattern 730. In another example embodiment, the conductive pattern 710 may have a different shape from the antenna pattern 730.

The antenna substrate 700 may further include a protection insulating layer 740 at least partially covering the antenna pattern 730 or the conductive pattern 710. In example an embodiment, the protection insulating layer 740 may not be provided.

The antenna pattern 730 may be connected to the first semiconductor chip 300 through one or more of the second redistribution substrate 600, the metal post 210, the vertical connection conductor 220, and the first redistribution substrate 100. The antenna pattern 730 may be configured to transmit or receive RF signals and to transmit the received RF signals to the first semiconductor chip 300 (e.g., a radio-frequency integrated circuit (RFIC)) through the second conductive pattern 620 in the second redistribution substrate 600, the metal post 210, and the vertical connection conductor 220. In an example embodiment, the antenna signal in the semiconductor device may have omnidirectional characteristics, depending on the structure and position of the antenna pattern 730, but example embodiments are not limited thereto.

At least one connector 800 may be disposed on the second redistribution substrate 600. The connector 800 may be disposed on the top surface of the second redistribution substrate 600. The connector 800 may be, for example, a module, configured to exchange signals between the semiconductor package and an external device.

The connector 800 may be disposed on the second redistribution substrate 600 in a face-down manner. For example, the connector 800 may be provided to have a front surface facing the second redistribution substrate 600 and a rear surface opposite to the second redistribution substrate 600. A pad or a wire may be, for example, provided on the front surface of the connector 800, and a coupling portion configured to couple with an external cable or an external device may be provided on the rear surface of the connector 800. The connector 800 may be mounted on the second redistribution substrate 600 through connector terminals 810 including, e.g., solder balls or solder bumps. The connector terminals 810 may be connected to the second upper pads of the second redistribution substrate 600, but example embodiments are not limited thereto

For conciseness of description, an element previously described with reference to FIG. 1 may be identified by the same reference number without repeating an overlapping description thereof. For example, in the following description technical features different from those of the example embodiments of FIG. 1 will mainly be mentioned.

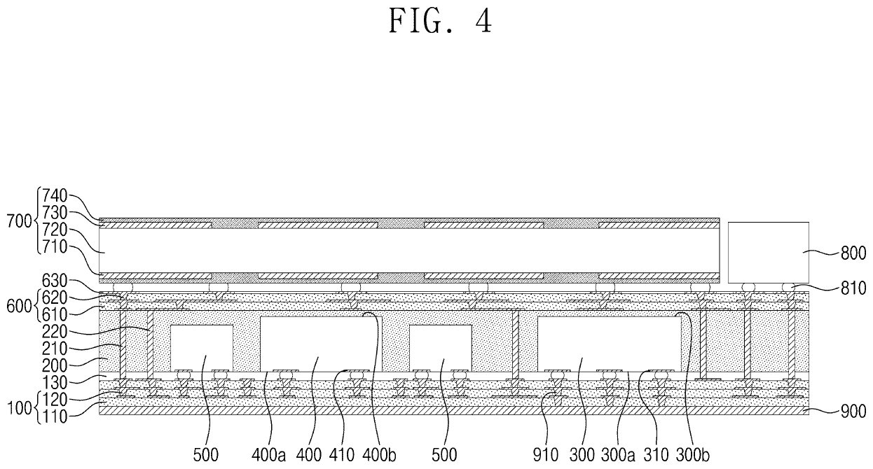

FIG. 4 is a sectional view illustrating a semiconductor package according to some example embodiments of inventive concepts.

Referring to FIG. 4, the antenna substrate 700 may be disposed on the second redistribution substrate 600. The antenna substrate 700 may be mounted on the second redistribution substrate 600 in a flip-chip manner. For example, connection terminals including, e.g., solder balls or solder bumps, may be provided on the bottom surface of the antenna substrate 700. The connection terminals may be connected to the conductive pattern 710 or may be connected to additional pads that are distinct from the conductive pattern 710.

The antenna substrate 700 may be coupled to the first upper pads of the second redistribution substrate 600 using the connection terminals. The antenna substrate 700 may be electrically connected to the second redistribution substrate 600 through the connection terminals.

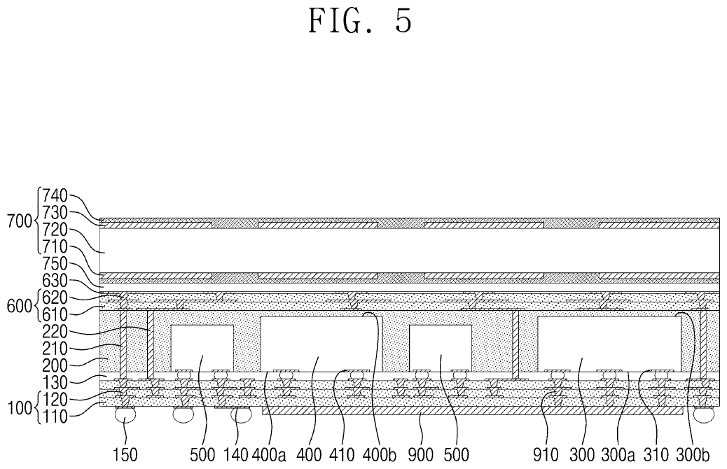

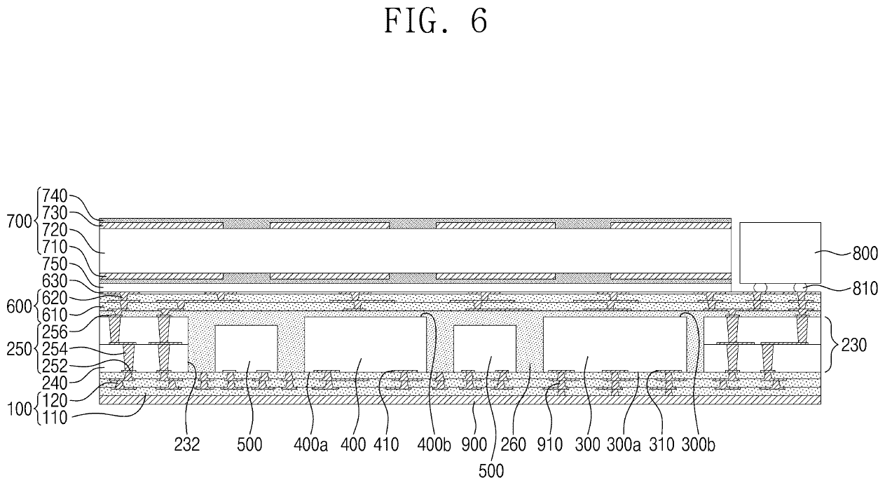

FIG. 5 is a sectional view illustrating a semiconductor package according to some example embodiments of inventive concepts.

Referring to FIG. 5, the connector 800 may not be provided, unlike the embodiment of FIG. 1. The antenna substrate 700 may be provided on the top surface of the second redistribution substrate 600. The antenna substrate 700 may cover part of or the entire top surface of the second redistribution substrate 600. For example, the antenna substrate 700 may be provided to have an increased area, and this may make it possible to improve the transmitting and receiving characteristics of antenna signals in a semiconductor package.

Outer pads 140 may be formed below the first redistribution substrate 100. The outer pads 140 may be coupled to the first conductive patterns 120. Outer terminals 150 may be provided on bottom surfaces of the outer pads 140. The outer terminals 150 may include solder balls or solder bumps. The semiconductor package may be, for example, classified as a ball grid array (BGA) package, a fine ball-grid array (FBGA) package, or a land grid array (LGA) package, depending on the kind and arrangement of the outer terminals 150, but example embodiments are not limited thereto. The outer terminals 150 may be electrically connected to the first semiconductor chip 300, the second semiconductor chip 400, and passive devices 500 by the first redistribution substrate 100. The semiconductor package may be mounted on an external device using the outer terminals 150. Since the outer pads 140 and the outer terminals 150 are provided, the connector 800 may not be disposed on the second redistribution substrate 600, but example embodiments are not limited thereto.

Although not shown, a substrate protection layer may be disposed on the bottom surface of the first redistribution substrate 100. The substrate protection layer may be provided to cover a bottom surface of the lowermost one of the first substrate wiring layers and at least partially expose the outer pads 140. The protection layer may include, for example, at least one of an insulating polymer (e.g., an epoxy-based polymer), an Ajinomoto Build-up Film (ABF), or organic materials or inorganic materials, but example embodiments are not limited thereto.

FIG. 6 is a sectional view illustrating a semiconductor package according to some example embodiments of inventive concepts.

Referring to FIG. 6, the semiconductor package may include a connection substrate 230, which may be provided in place of the metal post 210 and the vertical connection conductor 220. The connection substrate 230 may be, for example, disposed on the first redistribution substrate 100. An opening 232 may be provided, the opening being, for example, defined by and penetrating the connection substrate 230. For example, the opening 232 may be a region, for example an empty region or a filled region, which is formed in the shape of a hole to connect, and/or expose to each other, top and bottom surfaces of the connection substrate 230. A bottom surface of the connection substrate 230 may be in contact with the top surface of the first redistribution substrate 100. The connection substrate 230 may include a base layer 240 and a conductive portion 250, which may be a wiring pattern provided in the base layer 240. The conductive portion 250 may be a wiring structure that is used to vertically connect the first redistribution substrate 100 to the second redistribution substrate 600. In an example embodiment, the base layer 240 may be, for example, formed of or include at least silicon oxide. The conductive portion 250 may be disposed in an outer region of the connection substrate 230, as compared with the opening 232. The conductive portion 250 may include lower pads 252, vias 254, and upper pads 256. The lower pads 252 may be disposed on or below a bottom surface of the connection substrate 230. Although FIG. 6 illustrates an example embodiment in which the first conductive pattern 120 of the first redistribution substrate 100 is directly coupled to the lower pads 252 of the connection substrate 230, example embodiments are not limited thereto. Pads, which may be connected to the first conductive patterns 120, may be provided on the uppermost surface of the first redistribution substrate 100, and the connection substrate 230 may be mounted on the pads of the first redistribution substrate 100 using terminals including, e.g., solder balls or solder bumps, provided on the lower pads 252. Hereinafter, some example embodiments of inventive concepts will be further described with reference to FIG. 6.

Any of the upper pads 256 may include a protruding pattern that extends to a region on the top surface of the connection substrate 230. Alternatively, unlike the structure shown in FIG. 6, the upper pads 256 may be buried in the base layer 240, and the upper pads 256 may have top surfaces that are coplanar or substantially coplanar with the top surface of the connection substrate 230. The upper pads 256 may be electrically connected to the second conductive patterns 620 of the second redistribution substrate 600. The vias 254 may be provided to penetrate the base layer 240 and to electrically connect the lower pads 252 to the upper pads 256.

The lower pads 252 may be disposed on the bottom surface of the connection substrate 230. The lower pads 252 may be buried in the base layer 240 and may have bottom surfaces that are substantially coplanar with the bottom surface of the connection substrate 230. The vias 254 may be provided to penetrate the base layer 240 and to electrically connect the upper pads 256 to the lower pads 252. The base layer 240 may include, for example, a polymer material. For example, the base layer 240 may be formed of or include at least one of an insulating polymer or a photoimageable dielectric (PID) material, but example embodiments are not limited thereto. The photoimageable dielectric material may include at least one of, for example, photoimageable polyimide, polybenzoxazole (PBO), phenol-based polymers, or benzocyclobutene-based polymers. Alternatively, the base layer 240 may include at least one insulating material. For example, the base layer 240 may be formed of or include at least one of silicon oxide (SiO), silicon nitride (SiNx), silicon oxynitride (SiON), or various insulating polymer materials. The upper pads 256, the lower pads 252, and the vias 254 may be, for example, formed of or include at least one of conductive or metallic materials (e.g., copper (Cu)), but example embodiments are not limited thereto.

The first and second semiconductor chips 300 and 400 may be disposed on the first redistribution substrate 100. The first and second semiconductor chips 300 and 400 may be disposed in the opening 232 of the connection substrate 230. The first and second semiconductor chips 300 and 400 may be provided to have substantially the same features as those of FIG. 1. For example, the second semiconductor chip 400 may be horizontally spaced apart from the first semiconductor chip 300. The first and second semiconductor chips 300 and 400 may be spaced apart from an inner side surface of base layer 240, but example embodiments are not limited thereto.

At least one passive device 500 may be disposed on the first redistribution substrate 100. The passive device 500 may be disposed in the opening 232 of the connection substrate 230. Here, the passive device 500 may be provided to have substantially the same features as that of FIG. 1. For example, the passive device 500 may be horizontally spaced apart from the second semiconductor chip 400. The passive device 500 may be spaced apart from an inner side surface of the base layer 240.

A mold layer 260 may be provided on the first redistribution substrate 100. The mold layer 260 may at least partially cover a top surface of the under-fill layer 130. The mold layer 260 may enclose the first semiconductor chip 300, the second semiconductor chip 400, the passive device 500, and the connection substrate 230. The mold layer 260 may at least partially cover the first semiconductor chip 300, the second semiconductor chip 400, the passive device 500, and the connection substrate 230. The mold layer 260 may include, for example, an insulating material. For example, the mold layer 260 may be formed of or include an epoxy molding compound (EMC), but example embodiments are not limited thereto.

FIG. 1 illustrates an example embodiment in which the first semiconductor chip 300, the second semiconductor chip 400, and the passive device 500 are provided in a face-down manner, but the example embodiments are not limited thereto. For example, the first semiconductor chip 300, the second semiconductor chip 400, and the passive device 500 may be provided in a face-up manner.

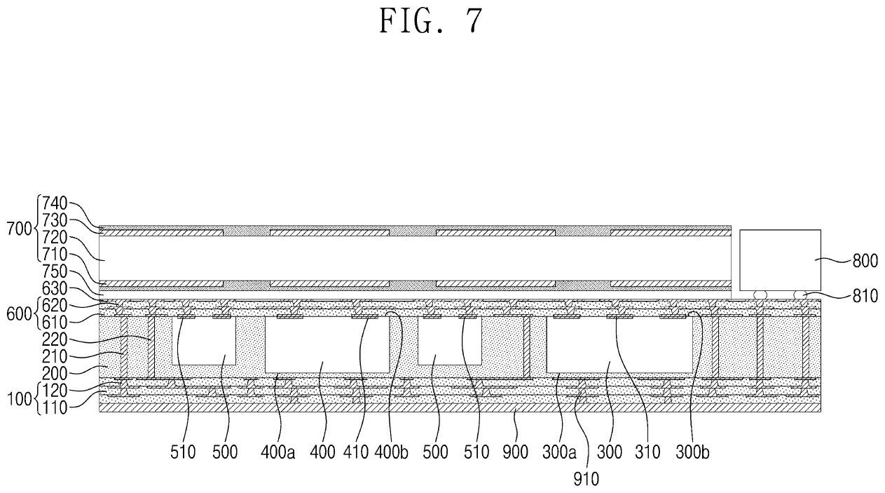

FIG. 7 is a sectional view illustrating a semiconductor package according to some example embodiments of inventive concepts.

Referring to FIG. 7, the heat-dissipation conductive patterns 910 may be disposed in the first redistribution substrate 100 to vertically penetrate the first redistribution substrate 100, similar to an example embodiment described with reference to FIG. 1. The heat-dissipation conductive patterns 910 may be some of the first conductive patterns 120 of the first redistribution substrate 100. For example, the heat-dissipation conductive pattern 910 may include a head portion and a tail portion, which are connected to each other as to form a single object. The head portion may be disposed on a bottom surface of the first insulating pattern 110, and the tail portion may extend in a vertical direction to penetrate at least one of the first insulating patterns 110.

The uppermost ones of the heat-dissipation conductive patterns 910 may be electrically disconnected from the first semiconductor chip 300, the second semiconductor chip 400, and the passive devices 500. Some of the lowermost ones of the heat-dissipation conductive pattern 910 may be connected to the heat-dissipation pad 900, but example embodiments are not limited thereto.

The first semiconductor chip 300 may be disposed on the first redistribution substrate 100. The top surface 300b may be an active surface of the first semiconductor chip 300. The bottom surface 300a may be an inactive surface of the first semiconductor chip 300. For example, the first semiconductor chip 300 may be disposed on the first redistribution substrate 100 in a face-up manner. The first semiconductor chip 300 may include the first chip pads 310 that are provided on the top surface 300b. The first chip pads 310 may be electrically connected to an integrated circuit in the first semiconductor chip 300.

The top surface 300b of the first semiconductor chip 300 may be in contact with a bottom surface of the second redistribution substrate 600. The first chip pads 310 may be electrically connected to the second conductive patterns 620 of the second redistribution substrate 600. For example, the second conductive pattern 620 of the lowermost one of the substrate wiring layers in the second redistribution substrate 600 may be exposed to a region on a bottom surface of the second insulating pattern 610. The lowermost one of the second conductive patterns 620 may be in direct contact with the first chip pads 310, on a contact surface between the first semiconductor chip 300 and the second redistribution substrate 600.

The second semiconductor chip 400 may be disposed on the first redistribution substrate 100. The top surface 400b may be an active surface of the second semiconductor chip 400. The bottom surface 400a may be an inactive surface of the second semiconductor chip 400. For example, the second semiconductor chip 400 may be disposed on the first redistribution substrate 100 in a face-up manner. The second semiconductor chip 400 may include the second chip pads 410, which are provided on the top surface 400b. The second chip pads 410 may be electrically connected to an integrated circuit in the second semiconductor chip 400.

The top surface 400b of the second semiconductor chip 400 may be in contact with the bottom surface of the second redistribution substrate 600. The second chip pads 410 may be electrically connected to the second conductive patterns 620 of the second redistribution substrate 600. In more detail, the lowermost one of the second conductive patterns 620 may be in direct contact with the second chip pads 410, on a contact surface between the second semiconductor chip 400 and the second redistribution substrate 600.

The passive device 500 may be horizontally spaced apart from the second semiconductor chip 400, on the top surface of the first redistribution substrate 100. The passive device 500 may be provided in a face-up manner. For example, the top surface of the passive device 500 may be a front surface. For example, passive device pads 510 may be provided on the top surface of the passive device 500. The top surface of the passive device 500 may be located at the same or substantially the same level as the top surface of the mold layer 200. For example, the top surface of the passive device 500 may be coplanar or substantially coplanar with the top surface of the mold layer 200. A bottom surface of the passive device 500 may be located at a level that is equal to or higher than a bottom surface of the mold layer 200. For example, the passive device 500 may not protrude to a region on the bottom surface of the mold layer 200, but example embodiments are not limited thereto.

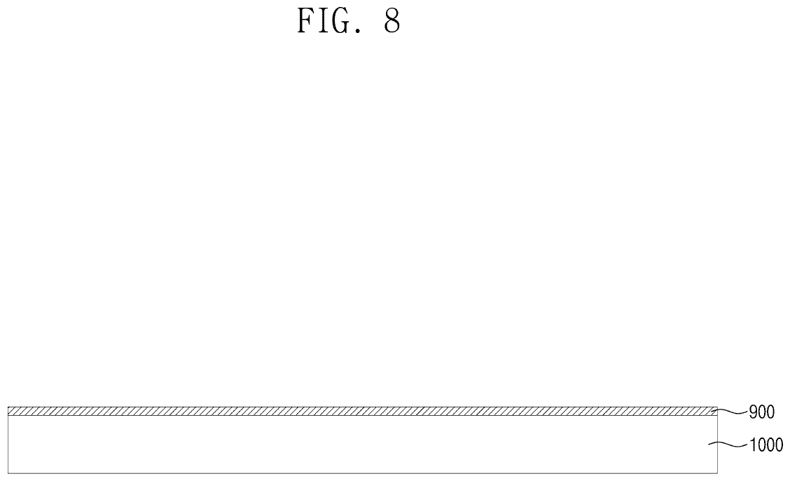

FIGS. 8 to 12 are sectional views illustrating a method of fabricating a semiconductor package, according to some example embodiments of inventive concepts.

Referring to FIG. 8, a carrier substrate 1000 may be provided. Although not shown, a metal seed may be provided on a top surface of the carrier substrate 1000. For example, plating process using the metal seed as a seed may be performed to form the heat-dissipation pad 900, but example embodiments are not limited thereto.

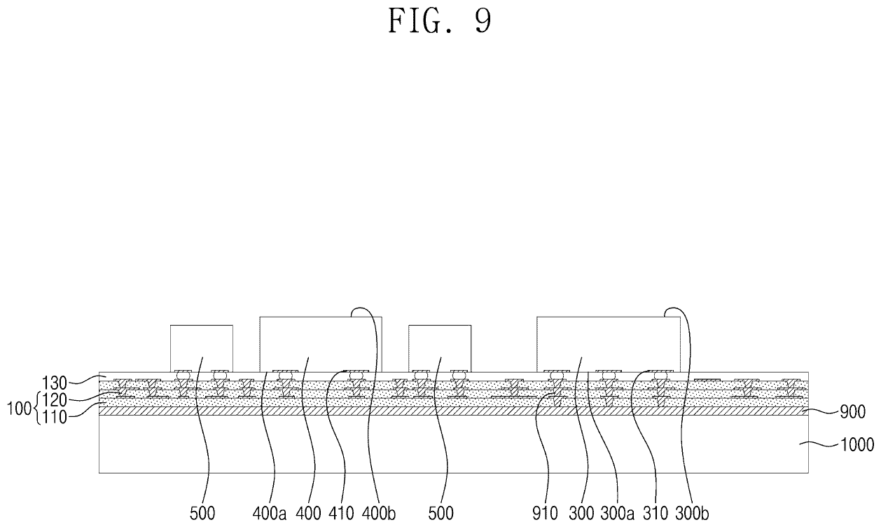

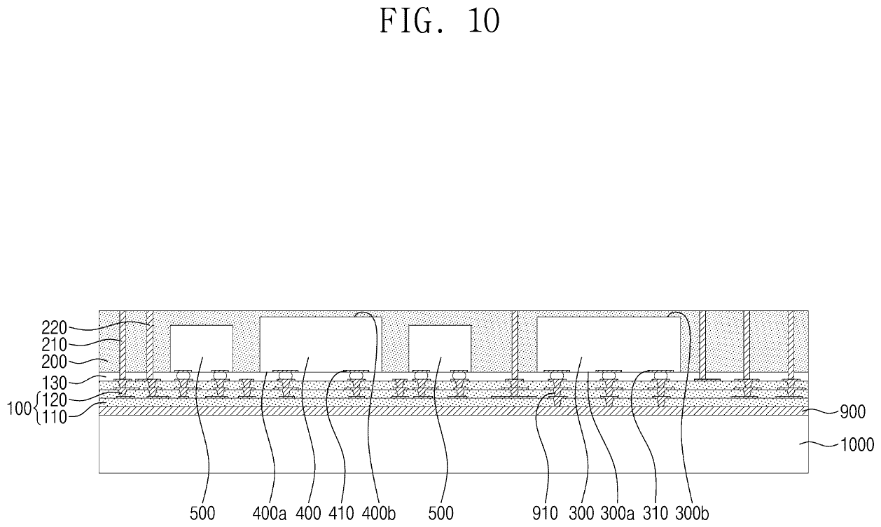

Referring to FIG. 9, the first redistribution substrate 100 may be formed on the heat-dissipation pad 900. For example, the first insulating pattern 110 and the first conductive pattern 120 may be formed on a top surface of the heat-dissipation pad 900 to fabricate the first redistribution substrate 100. For example, the first insulating pattern 110 may be formed by forming an insulating layer on the top surface of the heat-dissipation pad 900 and patterning the insulating layer. The first conductive pattern 120 may be formed by forming a conductive layer on the insulating layer and patterning the conductive layer. A portion of the first conductive pattern 120 may be exposed to a region on the first insulating pattern 110. Each substrate wiring layer may be formed by the afore-described process, and the first redistribution substrate 100, which includes a plurality of substrate wiring layers, may be formed by repeating the afore-described process. At least one of the first conductive patterns 120 in the first redistribution substrate 100 may correspond to the heat-dissipation conductive pattern 910.

The under-fill layer 130 may be provided between the top surface of the first redistribution substrate 100 and the bottom surfaces of the first semiconductor chip 300, the second semiconductor chip 400, and the passive device 500. The under-fill layer 130 may fill spaces between the first redistribution substrate 100 and the first semiconductor chip 300, the second semiconductor chip 400, and the passive device 500. The under-fill layer 130 may enclose the connection terminals, but example embodiments are not limited thereto.

The first conductive pattern 120 in the uppermost one of the substrate wiring layers may serve as one of first, second, and third substrate pads, which are respectively used to mount the first semiconductor chip 300, the second semiconductor chip 400, and the passive device 500 on the first redistribution substrate 100.

The first semiconductor chip 300, the second semiconductor chip 400, and the passive device 500 may be provided on the first redistribution substrate 100. Here, the first semiconductor chip 300, the second semiconductor chip 400, and the passive device 500 may be disposed such that the active surfaces thereof face the first redistribution substrate 100.

Referring to FIG. 10, the mold layer 200 may be formed on the first redistribution substrate 100. The mold layer 200 may fill the spaces between the first redistribution substrate 100 and the first semiconductor chip 300, the second semiconductor chip 400, and the passive device 500. For example, the mold layer 200 may be formed by forming an insulating material between the first redistribution substrate 100 and the first semiconductor chip 300, the second semiconductor chip 400, and the passive device 500 and curing the insulating material. In an example embodiment, the mold layer 200 may cover the first semiconductor chip 300, the second semiconductor chip 400, and the passive device 500. However, in another example embodiment, the top surface 300b of the first semiconductor chip 300, the top surface 400b of the second semiconductor chip 400, and the top surface of the passive device 500 may be exposed to a region on the top surface of the mold layer 200.

The metal post 210 may be formed in the mold layer 200. For example, a penetration hole may be formed to penetrate the mold layer 200 and to expose the first conductive pattern 120. The metal post 210 may be formed by filling the penetration hole with a conductive material, but example embodiments are not limited thereto

The vertical connection conductor 220 may be formed in the mold layer 200. The vertical connection conductor 220 may have a shape the same as, substantially the same as, or similar to a partition wall crossing a region between the first and second semiconductor chips 300 and 400, enclosing each of the first and second semiconductor chips 300 and 400, and/or enclosing all of the first and second semiconductor chips 300 and 400. In an example embodiment, the vertical connection conductor 220 may be formed through the same process or a process substantially the same as or similar to a process of forming the metal post 210. For example, a trench may be formed to penetrate the mold layer 200. The vertical connection conductor 220 may be formed by filling the trench with a conductive material, but example embodiments are not limited thereto

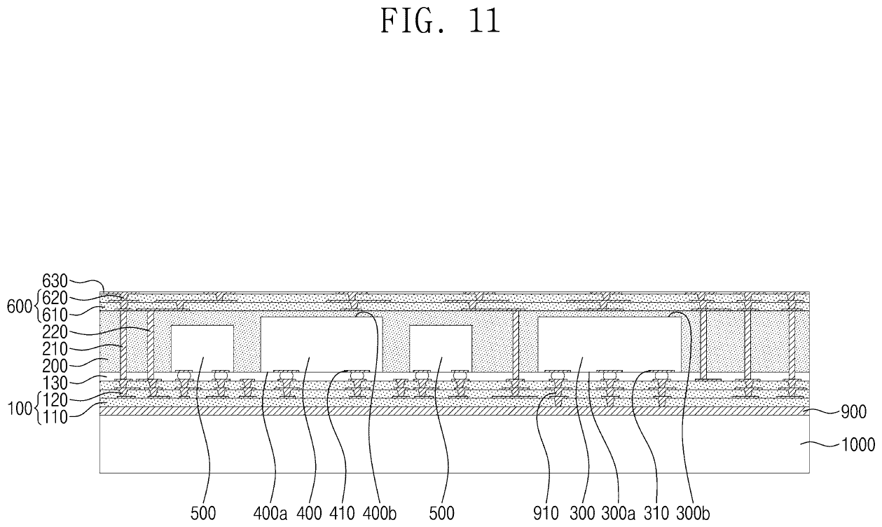

Referring to FIG. 11, the second redistribution substrate 600 may be formed on the top surface of the mold layer 200. For example, the second insulating pattern 610 and the second conductive pattern 620 may be formed on the top surface of the mold layer 200 to fabricate the second redistribution substrate 600. For example,, the second insulating pattern 610 may be formed by forming an insulating layer on the top surface of the mold layer 200 and patterning the insulating layer. The second conductive pattern 620 may be formed by forming a conductive layer on the insulating layer and patterning the conductive layer. Here, a portion of the second conductive pattern 620 may be exposed to a region on the second insulating pattern 610. Each substrate wiring layer may be formed by the afore-described process, and the second redistribution substrate 600, which includes a plurality of substrate wiring layers, may be formed by repeating the afore-described process. The uppermost one of the conductive layers may be patterned to form first upper pads and second upper pads. The first upper pads and the second upper pads may be coupled to the antenna substrate 700 and the connector 800, respectively, but example embodiments are not limited thereto.

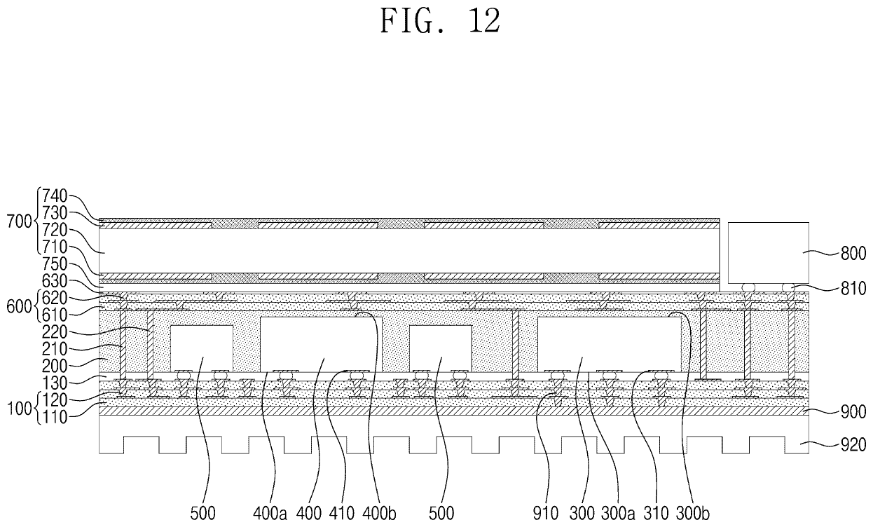

Referring to FIG. 12, the carrier substrate 1000 may be removed to expose the bottom surface of the heat-dissipation pad 900. In the case where an adhesive member (not shown) is present on the carrier substrate 1000, the adhesive member may also be removed when the carrier substrate 1000 is removed.

The heat sink 920 may be connected to the bottom surface of the heat-dissipation pad 900. Although not shown, the heat sink 920 may be connected to the heat-dissipation pad 900 through an adhesive member.

The antenna substrate 700 and the connector 800 may be disposed on the second redistribution substrate 600. The antenna substrate 700 may be attached to the second redistribution substrate 600 using the adhesive layer 750. For example, the adhesive layer 750 may be provided on the top surface of the second redistribution substrate 600, and then, the antenna substrate 700 may be placed on a top surface of the adhesive layer 750 and may be attached to the second redistribution substrate 600. The connector 800 may be disposed on the second redistribution substrate 600 in a flip chip manner. For example, the connector 800 may be provided such that a front surface thereof faces the second redistribution substrate 600. Here, the connector 800 may be mounted on the second redistribution substrate 600 through the connector terminals 810 (e.g., solder balls or solder bumps).

The semiconductor package according to some example embodiments of inventive concepts may be formed by the afore-described method.

In a semiconductor package according to some example embodiments of inventive concepts, both of first and second semiconductor chips, which may be configured to control an antenna pattern, may be provided in a single package provided with the antenna pattern, and thus, it may be possible to realize a semiconductor package with improved electrical characteristics and a reduced size.

In addition, since a semiconductor chip is placed in an inner portion of the package, an additional element for shielding electromagnetic waves may not be required. Thus, it may be possible to simplify a process of fabricating a semiconductor package and reduce cost for the fabrication process.

Furthermore, a heat-dissipation via pattern may be provided to connect the semiconductor chip to a heat-dissipation pad, and this feature may make it possible to improve the thermal stability of the semiconductor package.

While example embodiments of the inventive concept have been particularly shown and described, it will be understood by one of ordinary skill in the art that variations in form and detail may be made therein without departing from the spirit and scope of the attached claims.

Although example embodiments of inventive concepts have been described with reference to the accompanying drawings, it will be apparent to those skilled in the art that inventive concepts may be realized in various forms without being limited to the above-described example embodiments and may be embodied in other specific forms without departing from the technical spirit and essential characteristics. Thus, the above example embodiments are to be considered in all respects as illustrative and neither limiting nor restrictive.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A semiconductor package, comprising:
a first redistribution substrate;
a first semiconductor chip on the first redistribution substrate;
a second semiconductor chip horizontally apart from the first semiconductor chip;
a mold layer on the first redistribution substrate and enclosing the first and second semiconductor chips;
a second redistribution substrate on the mold layer;
a connection member horizontally apart from the first and second semiconductor chips and connecting the first redistribution substrate to the second redistribution substrate; and
an antenna substrate attached to the second redistribution substrate by an adhesive layer,
wherein the antenna substrate comprises
a core portion;
an antenna pattern on a top surface of the core portion; and
a wiring pattern on a bottom surface of the core portion.

2. The semiconductor package of claim 1, wherein the first semiconductor chip includes a radio-frequency integrated circuit (RFIC), and
the second semiconductor chip includes a power management integrated circuit (PMIC).

3. The semiconductor package of claim 1, further comprising:
at least one passive device on a top surface of the first redistribution substrate and horizontally apart from the second semiconductor chip.

4. The semiconductor package of claim 3, wherein the passive device includes at least one of a capacitor or an inductor.

5. The semiconductor package of claim 1, further comprising:
a connector on the second redistribution substrate and horizontally apart from the antenna substrate.

6. The semiconductor package of claim 1, further comprising:
a heat-dissipation pad on a bottom surface of the first redistribution substrate,
wherein the heat-dissipation pad and the first semiconductor chip are connected to each other by a heat-dissipation via pattern, the heat-dissipation via pattern vertically penetrating the first redistribution substrate.

7. The semiconductor package of claim 1, wherein the mold layer fills a space between the first and second redistribution substrates, and
the connection member comprises a metal post vertically penetrating the mold layer and connected to the first and second redistribution substrates.

8. The semiconductor package of claim 1, further comprising:
a connection substrate between the first and second redistribution substrates, the connection substrate defining and being penetrated by an opening,
wherein the first and second semiconductor chips are in the opening,
in the opening, the mold layer fills spaces between the connection substrate and the first semiconductor chip and between the connection substrate and the second semiconductor chip, and
the connection member comprises a wiring pattern in the connection substrate.

9. The semiconductor package of claim 1, further comprising:
a vertical connection conductor vertically penetrating the mold layer and connecting the first redistribution substrate to the second redistribution substrate,
wherein the vertical connection conductor is shaped like a partition wall enclosing the first and second semiconductor chips.

10. A semiconductor package, comprising:
a first redistribution substrate;
a first semiconductor chip on a top surface of the first redistribution substrate;
a second redistribution substrate on the first semiconductor chip;
a connection member at a side of the first semiconductor chip and connecting the first redistribution substrate to the second redistribution substrate;
an antenna substrate on the second redistribution substrate;
a heat-dissipation pad on a bottom surface of the first redistribution substrate; and
a heat-dissipation via pattern vertically penetrating the first redistribution substrate and connecting the heat-dissipation pad to the first semiconductor chip.

11. The semiconductor package of claim 10, further comprising:
a second semiconductor chip horizontally apart from the first semiconductor chip.

12. The semiconductor package of claim 11, wherein the first semiconductor chip comprises a radio-frequency integrated circuit (RFIC), and
the second semiconductor chip comprises a radio-frequency integrated circuit (RFIC).

13. The semiconductor package of claim 10, further comprising:
one or more passive devices on the top surface of the first redistribution substrate and horizontally apart from the first semiconductor chip; and
a connector on the second redistribution substrate and horizontally apart from the antenna substrate.

14. The semiconductor package of claim 10, further comprising:
a mold layer filling a space between the first and second redistribution substrates,
wherein the connection member comprises a metal post vertically penetrating the mold layer and connecting the first redistribution substrate to the second redistribution substrate.

15. The semiconductor package of claim 10, further comprising:
a connection substrate between the first and second redistribution substrates, the connection substrate defining and being penetrated by an opening, the first and second semiconductor chips being in the opening; and
in the opening, an insulating layer filling a space between the connection substrate and the first and second semiconductor chips,
wherein the connection member comprises a wiring pattern in the connection substrate.

16. The semiconductor package of claim 10, wherein the antenna substrate is connected to the second redistribution substrate by an adhesive layer including a die attach film (DAF), or the antenna substrate is connected to the second redistribution substrate by connection terminals including at least one of solder balls or solder bumps.

17. A semiconductor package, comprising:
a first redistribution substrate;
a first semiconductor chip on a top surface of the first redistribution substrate;
a second semiconductor chip on the first redistribution substrate and horizontally apart from the first semiconductor chip;
a mold layer on the top surface of the first redistribution substrate and enclosing the first and second semiconductor chips;
a second redistribution substrate on the mold layer;
an antenna substrate on the second redistribution substrate;
a connector on the second redistribution substrate and horizontally apart from the antenna substrate; and
a vertical connection conductor vertically penetrating the mold layer and connecting the first redistribution substrate to the second redistribution substrate,
wherein the vertical connection conductor is shaped like a partition wall enclosing the first and second semiconductor chips.

18. The semiconductor package of claim 17, further comprising:
a heat-dissipation pad disposed on a bottom surface of the first redistribution substrate,
wherein the heat-dissipation pad and the first semiconductor chip are connected to each other by a heat-dissipation via pattern, the heat-dissipation via pattern vertically penetrating the first redistribution substrate.

19. The semiconductor package of claim 17, wherein the antenna substrate is connected to the second redistribution substrate by an adhesive layer including a die attach film (DAF), or the antenna substrate is connected to second redistribution substrate by connection terminals including at least one of solder balls or solder bumps.

20. The semiconductor package of claim 17, further comprising:
a plurality of passive devices on the top surface of the first redistribution substrate and horizontally apart from the first and second semiconductor chips.
